(19) United States
(12) Patent Application Publication
(10) Pub. No.: US 2013/0295733 A1
(43) Pub. Date: Nov. 7, 2013

(54) Si-Ge-Si SEMICONDUCTOR STRUCTURE HAVING DOUBLE COMPOSITIONALLY-GRADED HETERO-STRUCTURES AND METHOD FOR FORMING THE SAME

(71) Applicants: Jing Wang, Beijing (CN); Jun Xu, Beijing (CN); Lei Guo, Beijing (CN)

(72) Inventors: Jing Wang, Beijing (CN); Jun Xu, Beijing (CN); Lei Guo, Beijing (CN)

(73) Assignee: TSINGHUA UNIVERSITY, Beijing (CN)

(21) Appl. No.: 13/935,850

(22) Filed: Jul. 5, 2013

Related U.S. Application Data
(62) Division of application No. 13/126,722, filed on Apr. 28, 2011.

(30) Foreign Application Priority Data
Jul. 13, 2010 (CN) 201010230174.9

(51) Int. Cl. H01L 29/66

(52) U.S. Cl. CPC H01L 29/665
USPC 438/191

(57) ABSTRACT

A Si—Ge—Si semiconductor structure having double compositionally-graded hetero-structures is provided, comprising: a substrate; a buffer layer or an insulation layer formed on the substrate; a strained SiGe layer formed on the buffer layer or the insulation layer, wherein a Ge content in a central portion of the strained SiGe layer is higher than the Ge content in an upper surface or in a lower surface of the strained SiGe layer, and the Ge content presents a compositionally-graded distribution from the central portion to the upper surface and to the lower surface respectively. According to the present disclosure, a compositionally-graded hetero-structure replaces an abrupt hetero-structure so as to form a triangular hole carrier potential well, so that most of hole carriers may be distributed in the strained SiGe layer with high Ge content and a reduction of the carrier mobility caused by interface scattering may be avoided, thus further improving a performance of a device.

### CROSS REFERENCE TO RELATED APPLICATIONS

This is a divisional patent application of U.S. patent application Ser. No. 13/126,722, filed on Apr. 28, 2011, which was a §371 national stage patent application based on International patent Application No. PCT/CN2010/080641, filed Dec. 31, 2010, entitled “Si—Ge—Si SEMICONDUCTOR STRUCTURE HAVING DOUBLE GRADED JUNCTIONS AND METHOD FOR FORMING THE SAME,” which claims the priority and benefit of Chinese Patent Application No. 201010230174.9, filed on Jul. 13, 2010, which are each incorporated herein by reference in their entirety.

### FIELD

The present disclosure relates to semiconductor manufacture and design, and more particularly to a Si—Ge—Si semiconductor structure having double compositionally-graded hetero-structures and a method for forming the same.

### BACKGROUND

Recently, with a continuous scaling down of a field-effect transistor feature size, a working speed thereof is faster and faster. However, a feature size of the field-effect transistor has reached a physical limit thereof, and therefore it will become more and more difficult to improve the speed of the field-effect transistor by reducing the feature size thereof.

Therefore, a CMOS device with silicon as a channel material has a lowered mobility, which may not meet performance improvement thereof. In order to solve this problem, conventionally, strained silicon techniques are adopted to improve the mobility of silicon, or other materials with higher mobility are used to replace the silicon as the channel material for the device, among which Ge has obtained more attention than ever before because of its higher hole carrier mobility. Because researches have shown that Ge and SiGe with high Ge content both have a much higher hole carrier mobility than Si, Ge or SiGe is most suitable for fabricating PMOS devices in future CMOS process.

However, a conventional field-effect transistor with Ge as the channel material still has the following defects of: a BTBT (Band To Band Tunneling) interband leakage caused by narrow bandgap, poor interface between a channel layer and a gate dielectric layer, extremely low activation coefficient at a drain and a source, a large junction depth due to an extremely easy diffusion of implanting and doping at the high temperature, etc.

Therefore, conventionally, a Si—Ge—Si structure is proposed to overcome the above defects. FIG. 1 is a cross-sectional view of a conventional Si—Ge—Si structure. As shown in FIG. 1, a buffer layer 120 is formed on a substrate 110, and a first strained Si layer 130, a strained Ge layer 140 and a second strained Si layer 150 are formed sequentially on the buffer layer 120. With the conventional Si—Ge—Si structure, the BTBT leakage may be effectively suppressed, and an interface state between Ge materials and gate materials may be effectively improved. In addition, a hole carrier potential well may be formed in the Si—Ge—Si structure, so that most of hole carriers may be distributed in the strained Ge layer, thus further increasing the mobility of the carriers and improving a performance of the device.

Conventionally, because two Si—Ge and Ge—Si abrupt interfaces are formed in the Si—Ge—Si structure, the interface state may be generated between two materials of Si and Ge, and thus a transportation of the carriers may be scattered and consequently the mobility of the carriers may be reduced.

### SUMMARY

The present disclosure is aimed to solve at least one of the above mentioned technical problems, particularly a defect of reduced carrier mobility caused by an interface state between two abrupt interfaces.

According to an aspect of the present disclosure, a Si—Ge—Si semiconductor structure having double compositionally-graded hetero-structures is provided, comprising: a substrate; a buffer layer or an insulation layer formed on the substrate; a strained SiGe layer formed on the buffer layer or the insulation layer, wherein a Ge content in a central portion of the strained SiGe layer is higher than the Ge content in an upper surface or in a lower surface of the strained SiGe layer, and the Ge content presents a compositionally-graded distribution from the central portion to the upper surface and to the lower surface respectively.

In one embodiment, the Si—Ge—Si semiconductor structure further comprises a gate stack formed on the strained SiGe layer and one or more side walls formed on two sides of the gate stack; and a source and a drain formed in the strained SiGe layer and on the two sides of the gate stack respectively.

In one embodiment, the strained SiGe layer is formed by a low temperature chemical vapor deposition, and the Ge content in a source gas is controlled during the low temperature chemical vapor deposition so that the Ge content presents the compositionally-graded distribution from the central portion to the upper surface and to the lower surface respectively.

In one embodiment, the strained SiGe layer is formed by an ultrahigh vacuum chemical vapor deposition at a temperature within a range from 200° C. to 550° C.

In one embodiment, the strained SiGe layer is formed by a low temperature reduced pressure chemical vapor deposition at a temperature within a range from 300° C. to 600° C.

In one embodiment, a triangular hole carrier potential well is formed in the strained SiGe layer.

According to another aspect of the present disclosure, a method for forming a Si—Ge—Si semiconductor structure having double compositionally-graded hetero-structures is provided, comprising steps of: providing a substrate; forming a buffer layer or an insulation layer on the substrate; forming a strained SiGe layer on the buffer layer or the insulation layer by using a low temperature chemical vapor deposition and controlling a content of Ge in a source gas, wherein a Ge content in a central portion of the strained SiGe layer is higher than the Ge content in an upper surface or in a lower surface of the strained SiGe layer, and the Ge content presents a compositionally-graded distribution from the central portion to the upper surface and to the lower surface respectively.

In one embodiment, the method further comprises steps of: forming a gate stack on the strained SiGe layer and forming one or more side walls on two sides of the gate stack; and forming a source and a drain in the strained SiGe layer and on the two sides of the gate stack respectively.

In one embodiment, the strained SiGe layer is formed by an ultrahigh vacuum chemical vapor deposition at a temperature within a range from 200° C. to 550° C.

In one embodiment, the strained SiGe layer is formed by a low temperature reduced pressure chemical vapor deposition at a temperature within a range from 300° C. to 600° C.

In one embodiment, during the low temperature chemical vapor deposition, a mixed gas of SiH₄ and GeH₄ is used as a precursor and a flow rate ratio of GeH₄ to SiH₄ first increases gradually and then decreases gradually.

In one embodiment, a temperature first decreases gradually and then increases gradually during the low temperature chemical vapor deposition.

According to an embodiment of the present disclosure, the distribution of the Ge content may be controlled by the flow rate and/or the temperature. According to an embodiment of the present disclosure, a compositionally-graded hetero-structure replaces an abrupt hetero-structure so as to form the triangular hole carrier potential well, so that most of the hole carriers may be distributed in the layer with high Ge content and a reduction of the carrier mobility caused by interface scattering may be avoided, thus further improving the performance of the device.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a cross-sectional view of a conventional Si—Ge—Si structure;

FIG. 2 is a cross-sectional view of a Si—Ge—Si semiconductor structure having double compositionally-graded hetero-structures according to a first embodiment of the present disclosure;

FIG. 3 is a cross-sectional view of a Si—Ge—Si semiconductor structure having double compositionally-graded hetero-structures according to a second embodiment of the present disclosure; and

FIG. 4 is a cross sectional diagram of an intermediate status of a Si—Ge—Si semiconductor structure formed during a process of a method for forming the Si—Ge—Si semiconductor structure having double compositionally-graded hetero-structures according to an embodiment of the present disclosure.

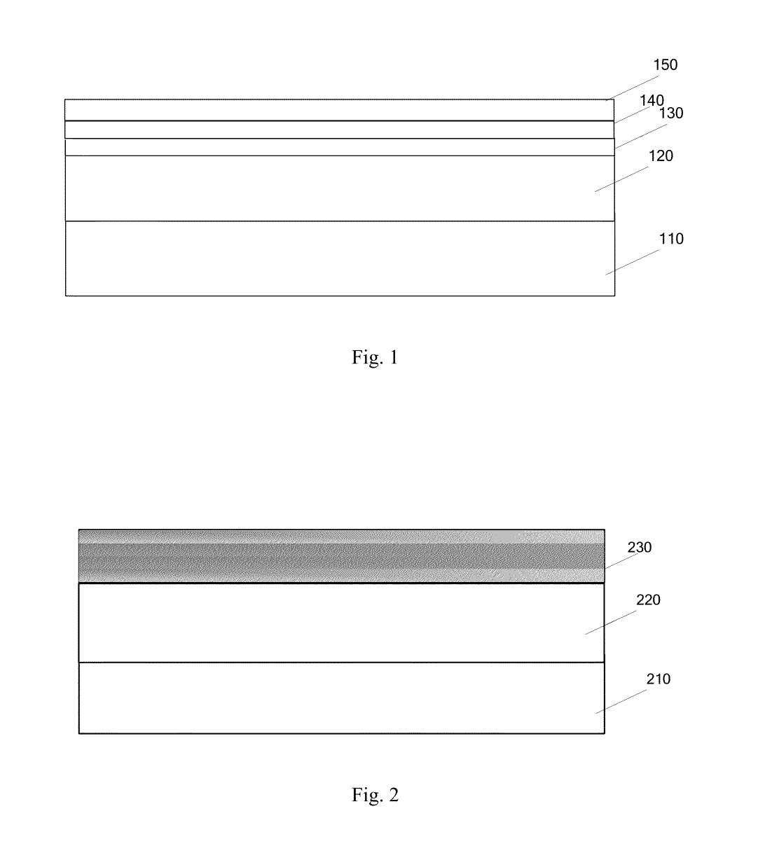

### DETAILED DESCRIPTION OF EMBODIMENTS OF THE DISCLOSURE

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

Various embodiments and examples are provided in the following description to implement different structures of the present disclosure. In order to simplify the present disclosure, certain elements and settings will be described. However, these elements and settings are only examples and are not intended to limit the present disclosure. In addition, reference numerals may be repeated in different examples in the disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied. Moreover, a structure in which a first feature is “on” a second feature may include an embodiment in which the first feature directly contacts the second feature and may include an embodiment in which an additional feature is prepared between the first feature and the second feature so that the first feature does not directly contact the second feature.

A main principle of the present disclosure lies in that a compositionally-graded hetero-structure replaces an abrupt hetero-structure so as to form a triangular hole carrier potential well. A Si—Ge—Si semiconductor structure having double compositionally-graded hetero-structures is provided according to the present disclosure. However, those skilled in the art may understand that modifications and alternatives of the Si—Ge—Si semiconductor structure having double compositionally-graded hetero-structures may be made, which should be included in the scope of the present disclosure.

FIG. 2 is a cross-sectional view of a Si—Ge—Si semiconductor structure having double compositionally-graded hetero-structures according to a first embodiment of the present disclosure. The Si—Ge—Si semiconductor structure may comprise a substrate 210; a buffer layer or an insulation layer 220 formed on the substrate 210; and a strained SiGe layer 230 formed on the buffer layer or the insulation layer 220. A Ge content in a central portion of the strained SiGe layer 230 is higher than the Ge content in an upper surface or in a lower surface of the strained SiGe layer 230, and the Ge content presents a compositionally-graded distribution from the central portion to the upper surface and to the lower surface respectively.

In one embodiment, the substrate 210 may be formed from any semiconductor substrate material, including, but not limited to, silicon, germanium, silicon germanide, silicon carbide, gallium arsenide, or any group III/V compound.

In one embodiment, the buffer layer may be a relaxed SiGe virtual substrate layer, and the insulation layer may be formed from insulating materials such as SiO₂. According to the embodiment of the present disclosure, if the insulation layer is selected, a strained Si layer may be formed on the insulation layer by a smart-cut technology before forming the strained SiGe layer 230.

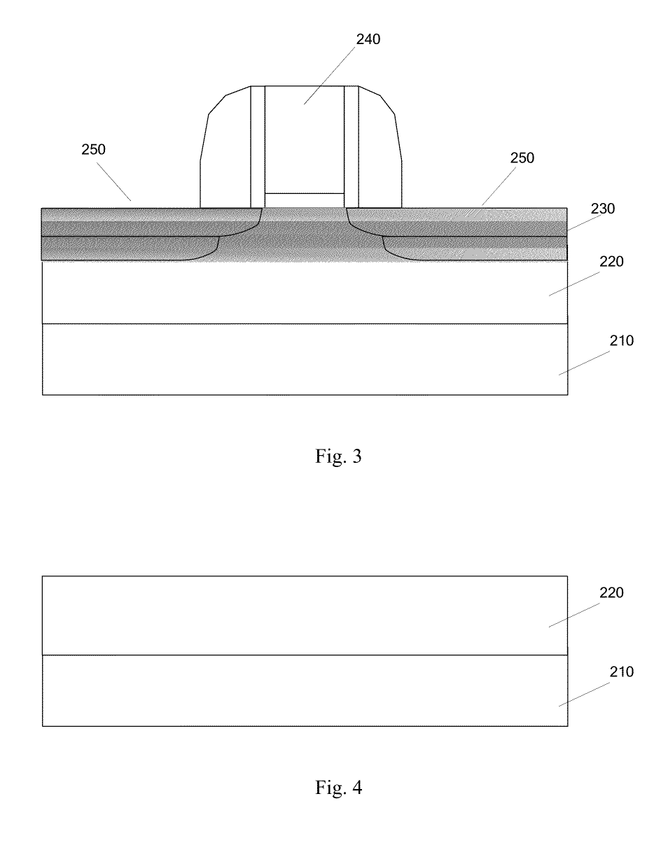

FIG. 3 is a cross-sectional view of a Si—Ge—Si semiconductor structure having double compositionally-graded hetero-structures according to a second embodiment of the present disclosure. The Si—Ge—Si semiconductor structure may further comprise a gate stack 240 formed on the strained SiGe layer 230 and a source and a drain 250 formed in the strained SiGe layer 230 and on the two sides of the gate stack 240 respectively. In one embodiment, the gate stack may comprise a gate dielectric layer and a gate and preferably, may comprise a high k gate dielectric layer and a metal gate. Certainly, the dielectric layer made from other nitrides or oxides, and the gate made from polycrystalline silicon may be used, which should also be within the scope of the present disclosure. In other embodiments, the gate stack 240 may further comprise a layer made from other materials to improve some or other properties of the gate. There is no limitation as to the structure of the gate stack and any type of gate structure may be used. In another embodiment, one or more side walls may be formed on two sides of the gate stack.

In the first and second embodiments of the present disclosure, the strained SiGe layer 230 is formed by a low temperature chemical vapor deposition, and the Ge content in a source gas is controlled during the low temperature chemical vapor deposition so that the Ge content presents the compositionally-graded distribution. Thus, not only a quality of the formed strained SiGe layer 230 is guaranteed, but also a growing speed is reduced. Therefore, the Ge content or a temperature may be controlled precisely and thus the Ge content may change continuously within a very thin thickness and consequently the triangular hole carrier potential well may be formed in the strained SiGe layer 230. In other embodiments, the Ge content may be controlled by changing the temperature. For example, the Ge content is reduced and the Si content is increased initially due to a high temperature and then the temperature is reduced gradually so as to reduce the Si content and to increase the Ge content; after the central portion is formed, the temperature is increased gradually and finally the stained SiGe layer 230 is formed. Preferably, the distribution of the Ge content may be controlled by controlling a flow rate of the gas and the temperature cooperatively, which will not be described in detail here.

In order to better understand the semiconductor structure according to an embodiment of the present disclosure, a method for forming the semiconductor structure described above is also provided. It should be noted that the semiconductor structure may be fabricated through various technologies, such as different types of product lines or different processes. However, if the semiconductor structures fabricated through various technologies have substantially the same structure and technical effects as those of the present disclosure, they should be within the scope of the present disclosure. In order to better understand the present disclosure, the method for forming the semiconductor structure of the present disclosure described above will be described in detail below. Moreover, it should be noted that the following steps are described only for exemplary and/or illustration purpose rather than for limitations. Other technologies may be adopted by those skilled in the art to form the semiconductor structure of the present disclosure described above.

FIG. 4 is a cross sectional diagram of an intermediate status of a Si—Ge—Si semiconductor structure formed during a process of a method for forming the Si—Ge—Si semiconductor structure having double compositionally-graded hetero-structures according to an embodiment of the present disclosure. The method may comprise the following steps.

Step S101, the substrate 210 is provided.

Step S102, the buffer layer or the insulation layer 220 is formed on the substrate 210, as shown in FIG. 4. In one embodiment, the buffer layer may be the relaxed SiGe virtual substrate layer, and the insulation layer may be formed from insulating materials such as SiO₂.

Step S103, the strained SiGe layer 230 is formed on the buffer layer or the insulation layer 220 by using the low temperature chemical vapor deposition and by controlling the Ge content in the source gas and/or temperature, as shown in FIG. 2. The Ge content in the central portion of the strained SiGe layer 230 is the largest, the Ge content in the upper surface and in the lower surface is the smallest and the Ge content presents a compositionally-graded distribution from the central portion to the upper surface and to the lower surface respectively.

In one embodiment, the strained SiGe layer 230 may be formed by an ultrahigh vacuum chemical vapor deposition at a temperature within a range from 200° C. to 550° C. and at a pressure within a range from 10⁻² pa to 10⁻³ pa.

In one embodiment, the strained SiGe layer is formed by a low temperature reduced pressure chemical vapor deposition at a temperature within a range from 300° C. to 600° C. and at a pressure within a range from 10 pa to 100 pa.

In the embodiments of the present disclosure, the strained SiGe layer 230 is formed by a low temperature chemical vapor deposition, and the Ge content in a source gas is controlled during the low temperature chemical vapor deposition so that the Ge content presents the compositionally-graded distribution. Thus, not only the quality of the formed strained SiGe layer 230 is guaranteed, but also the growing speed is reduced. Therefore, the Ge content may be controlled precisely and thus the Ge content may change continuously within a very thin thickness and consequently the triangular hole carrier potential well may be formed in the strained SiGe layer 230. In the above embodiments, during the low temperature chemical vapor deposition, a mixed gas of SiH₄ and GeH₄ is used as a precursor and a flow rate ratio of GeH₄ to SiH₄ first increases gradually and then decreases gradually. The increase of the flow rate ratio may be adjusted with a fixed step length or a variable step length, as long as the Ge content changes continuously and no abrupt interface occur.

In other embodiments of the present disclosure, the Ge content may be controlled by the temperature so that it changes continuously, since a decomposition rate of SiH₄ or SiH₄ is different at different temperatures. Under a certain temperature, the decomposition rate of GeH₄ is higher than that of SiH₄ and GeH₄ and SiH₄ have different lowest decomposition temperatures. Therefore, the Ge content in an epitaxial layer may be adjusted during a growing process by controlling the temperature. In a preferred embodiment, the distribution of the Ge content may be controlled by controlling the flow rate of the gas and the temperature cooperatively.

Step S104, the gate stack 240 is formed on the strained SiGe layer 230 and one or more side walls are formed on two sides of the gate stack 240.

Step S105, the source and the drain are formed in the strained SiGe layer 230 and on the two sides of the gate stack 240 respectively, as shown in FIG. 3.

According to the present disclosure, the compositionally-graded hetero-structures are used instead of the abrupt hetero-structures so as to form the triangular hole carrier potential well, so that most of the hole carriers may be distributed in the SiGe layer with high Ge content and a reduction of the carrier mobility caused by interface scattering may be avoided, thus further improving the performance of the device.

Although explanatory embodiments have been shown and described, it would be appreciated by those skilled in the art that changes, alternatives, and modifications all falling into the scope of the claims and their equivalents may be made in the embodiments without departing from spirit and principles of the disclosure.

What is claimed is:

1. A method for forming a Si—Ge—Si semiconductor structure having double compositionally-graded hetero-structures, comprising steps of:
providing a substrate;
forming a buffer layer or an insulation layer on the substrate;
forming a strained SiGe layer on the buffer layer or the insulation layer by using a low temperature chemical vapor deposition and controlling a content of Ge in a source gas,
wherein a Ge content in a central portion of the strained SiGe layer is higher than the Ge content in an upper surface or in a lower surface of the strained SiGe layer, and the Ge content presents a compositionally-graded distribution from the central portion to the upper surface and to the lower surface respectively.

2. The method according to claim 1, further comprising steps of:
forming a gate stack on the strained SiGe layer and forming one or more side walls on two sides of the gate stack; and
forming a source and a drain in the strained SiGe layer and on the two sides of the gate stack respectively.

3. The method according to claim 1, wherein the strained SiGe layer is formed by an ultrahigh vacuum chemical vapor deposition at a temperature within a range from 200° C. to 550° C.

4. The method according to claim 2, wherein the strained SiGe layer is formed by an ultrahigh vacuum chemical vapor deposition at a temperature within a range from 200° C. to 550° C.

5. The method according to claim 1, wherein the strained SiGe layer is formed by a low temperature reduced pressure chemical vapor deposition at a temperature within a range from 300° C. to 600° C.

6. The method according to claim 2, wherein the strained SiGe layer is formed by a low temperature reduced pressure chemical vapor deposition at a temperature within a range from 300° C. to 600° C.

7. The method according to claim 1, wherein during the low temperature chemical vapor deposition, a mixed gas of SiH₄ and GeH₄ is used as a precursor, and a flow rate ratio of GeH₄ to SiH₄ first increases gradually and then decreases gradually.

8. The method according to claim 1, wherein a temperature first decreases gradually and then increases gradually during the low temperature chemical vapor deposition.

9. The method according to claim 7, wherein a temperature first decreases gradually and then increases gradually during the low temperature chemical vapor deposition.
